(19) United States
(12) Patent Application Publication
(10) Pub. No.: US 2025/0251235 A1
(43) Pub. Date: Aug. 7, 2025

(54) VIA WAIST DEPTH DETECTION DEVICE AND METHOD FOR THROUGH GLASS VIA (TGV) SUBSTRATE

(71) Applicants: KUN-HSIEN CHENG, Taoyuan City (TW); Shyawei Optronics Corporation, Taoyuan City (TW)

(72) Inventor: KUN-HSIEN CHENG, Taoyuan City (TW)

(21) Appl. No.: 18/806,912

(22) Filed: Aug. 16, 2024

(30) Foreign Application Priority Data
Feb. 6, 2024 (TW) 113104786
Mar. 29, 2024 (TW) 113112182

(51) Int. Cl. G01B 11/06; H01L 23/15; H01L 23/498

(52) U.S. Cl. CPC G01B 11/06; H01L 23/15; H01L 23/49827

(57) ABSTRACT

A TGV substrate via waist depth detection device has a first DOF camera, a first collimated light source and microcontroller is illustrated. The first DOF camera and first collimated light source are respectively arranged above and below the glass substrate with at least one glass substrate via, and respectively obliquely face the upper surface and lower surface of the glass substrate. The microcontroller is coupled with the first DOF camera and first collimated light source. The first collimated light source is configured to emit the first collimated beam which obliquely irradiates the glass substrate, the first DOF camera is configured to obtain the first image, and the microcontroller is configured to obtain at least one detection result of at least one glass substrate via according to the first image.

### BACKGROUND

### Technical Field

The present disclosure relates to a via waist depth detection device and method for a through glass via (TGV) substrate, and more particularly, to the via waist depth detection device and method for the through glass via substrate, which use an oblique light source to irradiate a glass substrate and use a depth of field (DOF) camera to obliquely capture the glass substrate to obtain a detection result of glass substrate vias.

### Related Art

As conventional two-dimensional (2D) chip packaging techniques no longer meet the current requirements for speeds, performances and thinness of chips, two point five-dimensional (2.5D) and three-dimensional (3D) chip packaging techniques have been proposed. Both the 2.5D and 3D chip packaging techniques require interposers with vias to electrically connect different chips. In conventional techniques, a silicon substrate with through silicon vias (TSVs) (also known as TSV substrate) is used as the interposer. However, silicon is IV-A semiconductor material, and thus the surrounding carriers can move freely under the effects of electric or magnetic fields, such that the surrounding carriers which can move freely affect the adjacent circuits or signals, or even affect the performances of the chips. However, as the glass material has no freely moving charges, and also has an excellent dielectric performance and a coefficient of thermal expansion (CTE) which is close to a CTE of the silicon. Therefore, the glass substrate with through glass vias (TGVs) (also known as TGV substrate) is proposed to replace the TSV substrate as the interposer.

The method of manufacturing the glass substrate with the glass substrate vias is to irradiate laser at predetermined positions where the glass substrate vias are to be formed to modify material properties of the predetermined positions of the glass substrate, and then use immersion etching to form the glass substrate vias at the predetermined positions. Referring to FIG. 1 and FIG. 2, FIG. 1 is a schematic top view diagram of a glass substrate with glass substrate vias, and FIG. 2 is a schematic three-dimensional side view diagram of a cross section of the glass substrate with the glass substrate vias of FIG. 1, wherein the cross section of the glass substrate with the glass substrate vias shown in FIG. 2 is the cross section along a cross section line A-A in FIG. 1. The glass substrate 1 has a plurality of glass substrate vias 12 penetrating through the upper surface 10 and the lower surface 12 of the glass substrate 1. Each glass substrate via 12 has an upper opening 121 on the upper surface 10 and a lower opening 123 on the lower surface 11, and has a waist between the upper surface 10 and the lower surface 11, and the waist forms the via 122. The via 122 has a waist depth, and the waist depth of the via 122 is define a height difference between the upper surface 10 and the narrowest position of the via 122. The upper opening 121 and the lower opening 123 have opening diameters Rt and Rb respectively, and the via 122 of the waist has a via diameter Rm.

A ratio of the waist depth D over the opening diameter Rt or a ratio of a difference value (i.e., the thickness T minus the waist depth D) over the opening diameter Rb is an important parameter which is used to evaluate whether the glass substrate 1 meets the requirements or not. One conventional solution uses the X-ray to detect the glass substrate 1, but the detection speed of the X-ray is too slow, thus failing to meet the production benefits. Yet another conventional solution is to fill the glass substrate via 12 with lossless plastic material, and then take out the lossless plastic material for measuring the above information. However, the above manner requires filling the lossless plastic material which causes an extra cost and an extra detection time, and may also face the problem that the lossless plastic material remains in the glass substrate via 12. In view of this, it is necessary to propose a novel glass substrate via waist detection approach for the glass substrate with through glass vias to avoid the above technical problems.

### SUMMARY

According to any of the above objectives, the present disclosure provides a via waist depth detection device for a through glass via (TGV) substrate, which comprising a first depth of field (DOF) camera, a first collimated light source a microcontroller. The first depth of field camera and a first collimated light source are respectively arranged above and below a glass substrate with at least one glass substrate via, and obliquely face an upper surface and a lower surface of the glass substrate respectively, or alternatively, the first depth of field camera and a first collimated light source are respectively arranged below and above the glass substrate, and obliquely face the lower upper surface and the upper lower surface of the glass substrate respectively. The microcontroller is electrically connected with the first depth of field camera and the first collimated light source. The first collimated light source is configured to emit a first collimated beam which obliquely irradiates the glass substrate, the first depth of field camera is configured to obtain a first image, and the microcontroller is configured to obtain the at least one glass substrate via according to the first image.

According to the above objectives, the present disclosure further provides a via waist depth detection method for a through glass via substrate. The via waist depth detection method is executed by a via waist depth detection device for the through glass via substrate. The via waist depth detection device comprises a first depth of field camera, a first collimated light source, the first depth of field camera and the first collimated light source are respectively arranged above and below a glass substrate with at least one glass substrate via, and obliquely face an upper surface and a lower surface of the glass substrate respectively, or alternatively, the first depth of field camera and the first collimated light source are respectively arranged below and above the glass substrate, and obliquely face the lower surface and the upper surface of the glass substrate respectively. The via waist depth detection method comprises: controlling, by a microcontroller of the via waist depth detection device for the through glass via substrate, the first depth of field camera and the first collimated light source to make the first collimated light source emit a first collimated beam that obliquely irradiates the glass substrate and to make the first depth of field camera obtain a first image; and obtaining, by the microcontroller of the via waist depth detection device for the through glass via substrate, at least one detection result of the at least one glass substrate via according to the first image.

To summarize, the via waist depth detection device and method for the through glass via substrate provided by the present disclosure adopt an optical detection manner to detect a waist depth of the via of the through glass via substrate without filling lossless molding materials, therefore not only reducing the detection time and cost, but also avoiding the damage of the glass substrate.

### DESCRIPTIONS OF DRAWINGS

FIG. 1 is a schematic top view diagram of a glass substrate with glass substrate vias.

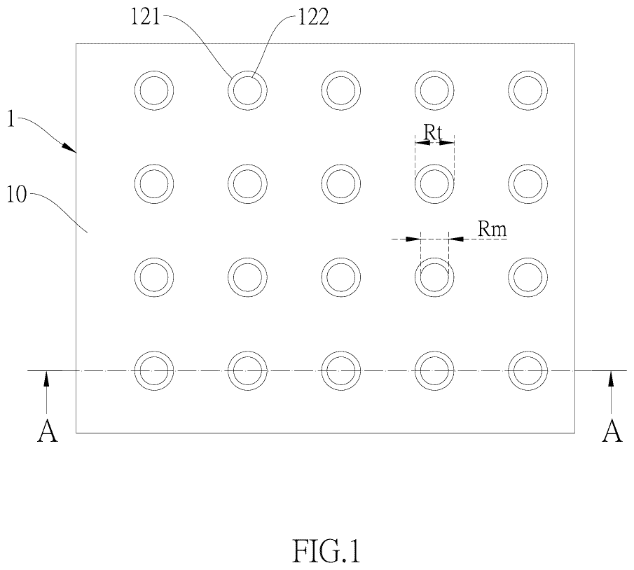

FIG. 2 is a schematic three-dimensional side view diagram of a cross section of the glass substrate with the glass substrate vias of FIG. 1.

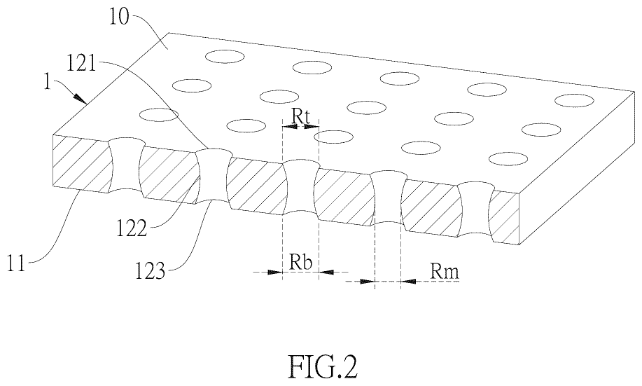

FIG. 3 is a schematic plane view diagram showing that a glass substrate is detected by a via waist depth detection device for the through glass via substrate according to an embodiment of the present disclosure.

FIG. 4 is a schematic side view cross section diagram showing that a glass substrate is detected by a via waist depth detection device for the through glass via substrate according to an embodiment of the present disclosure.

FIG. 5 a schematic diagram illustrating a first image and/or a second image. according to an embodiment of the present disclosure.

FIG. 6 a schematic diagram illustrating a first image and/or a second image according to another embodiment of the present disclosure.

FIG. 7 is a schematic side view cross section diagram showing that a glass substrate is detected by a via waist depth detection device for the through glass via substrate according to another embodiment of the present disclosure.

FIG. 8A is a schematic perspective view diagram illustrating a part of the structure of the via waist depth detection device for the through glass via substrate according to another embodiment of the present disclosure.

FIG. 8B is a schematic front view diagram illustrating a part of the structure of the via waist depth detection device for the through glass via substrate according to another embodiment of the present disclosure.

FIG. 8C is a schematic side view diagram illustrating a part of the structure of the via waist depth detection device for the through glass via substrate according to another embodiment of the present disclosure.

### DESCRIPTIONS OF EMBODIMENTS

In order to facilitate understanding of the technical features, advantages and technical effects of the present disclosure during examination, the present disclosure is illustrated in detail in the form of examples with the accompanying drawings. The drawings used herein are only for illustrative and auxiliary purposes, and the contents thereof may not be shown in the exact ratio and configuration. Hence, it should be noted that the shown ratios and configurations shall not be used to limit the scope of the present disclosure.

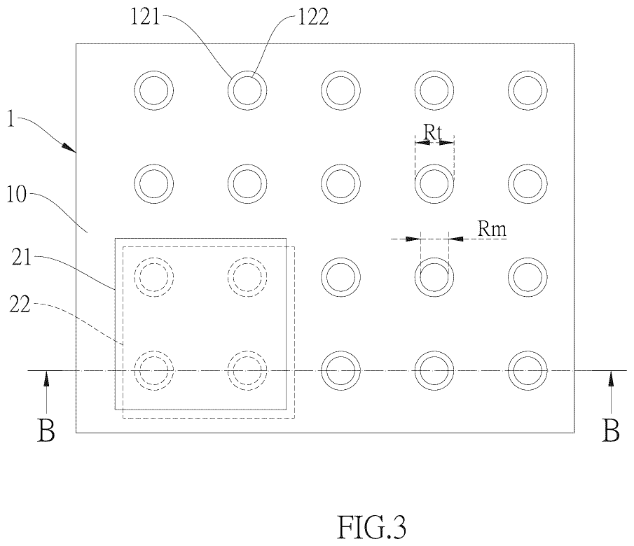

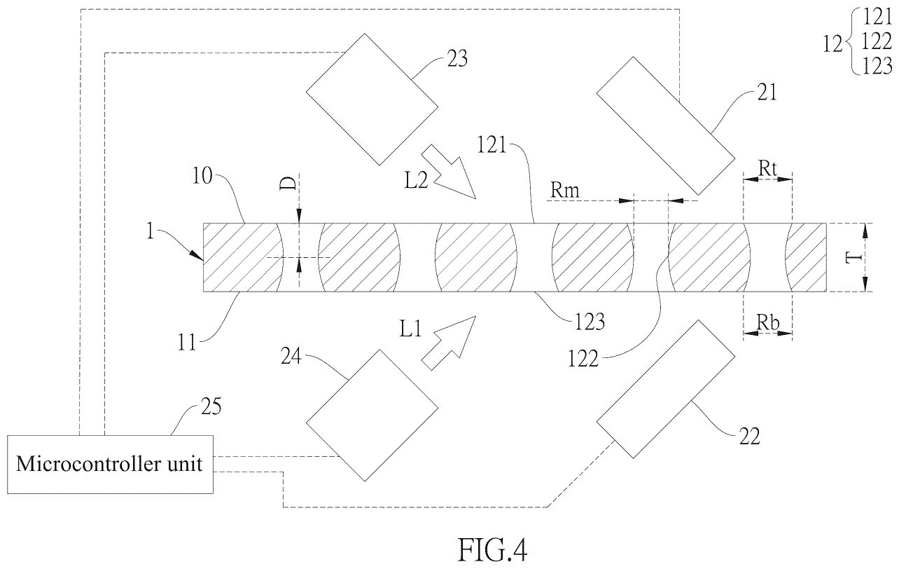

Please refer to FIG. 3 and FIG. 4. FIG. 3 is a schematic plane view diagram showing that a glass substrate is detected by a via waist depth detection device for the through glass via substrate according to an embodiment of the present disclosure, and FIG. 4 is a schematic side view cross section diagram showing that a glass substrate is detected by a via waist depth detection device for the through glass via substrate according to an embodiment of the present disclosure, wherein the cross-section of the glass substrate 1 in FIG. 4 is the cross section along the cross section line B-B in FIG. 3. The via waist depth detection device of the through glass via substrate at least comprises a first depth of field camera 21, a first collimated light source 24 and a microcontroller 25.

The first depth of field camera 21 and first collimated light source 24 are arranged above and below the glass substrate 1 with at least one glass substrate via 12 respectively, and obliquely face the upper surface 10 and lower surface 11 of the glass substrate 1 respectively; or alternatively, the first depth of field camera 21 and first collimated light source 24 are arranged below and above the glass substrate 1 respectively, and obliquely face the lower surface 11 and upper surface 10 of the glass substrate 1 respectively. In this embodiment, the first depth of field camera 21 and first collimated light source 24 are arranged above and below the glass substrate 1 with at least one glass substrate via 12 respectively. Specifically, the first depth of field camera 21 and first collimated light source 24 obliquely facing the upper surface 10 and lower surface 11 of the glass substrate 1 refers to that each of the extending direction of an image-capturing end of the first DOF camera 21 and the extending direction of an emitting end of the first collimated light source 24 has first inclination angle of 15-75 degrees from the upper surface 10 and lower surface 11 of the glass substrate 1, and preferably the first inclination angle of 30-45 degrees.

The microcontroller 25 is electrically connected with the first depth of field camera 21 and first collimated light source 24, and is configured to control the first depth of field camera 21 and first collimated light source 24. The first collimated light source 24 is configured to emit the first collimated beam L1 which obliquely irradiates the glass substrate 1. The first depth of field camera 21 is configured to obtain a first image. The microcontroller 25 is configured to obtain at least one detection result of at least one glass substrate via 12 according to the first image, wherein the detection result at least comprises a waist depth D of the glass substrate via 12. After the waist depth D and an upper opening diameter Rt are obtained, the depth-width ratio of the glass substrate via 12 can be calculated accordingly. The waist depth D of via 122 is defined as a height difference from the narrowest position of the via 122 to the upper surface 10 of the glass substrate 1. In addition, the collimation level of the first collimated beam L1 and a maximum determination depth of the first depth of field camera 21 relate to a via depth of the glass substrate via 12, i.e., the thickness T of the glass substrate 1.

Further, the via waist depth detection device for the through glass via substrate may further comprise a second depth of field camera 22 and a second collimated light source 23. When the first depth of field camera 21 and first collimated light source 24 are arranged above and below the glass substrate 1 respectively, the second depth of field camera 22 and second collimated light source 23 are arranged below and above the glass substrate 1 respectively, and obliquely face the lower surface 11 and upper surface 10 of the glass substrate 1 respectively. When the first depth of field camera 21 and first collimated light source 24 are arranged below and above the glass substrate 1 respectively, the second depth of field camera 22 and second collimated light source 23 are arranged above and below the glass substrate 1 respectively, and obliquely face the upper surface 10 and lower surface 11 of the glass substrate 1 respectively. In this embodiment, the second depth of field camera 22 and second collimated light source 23 are arranged below and above the glass substrate 1 respectively, and the second DOF camera 22 and second collimated light source 23 obliquely facing the lower surface 11 and upper surface 10 of the glass substrate 1 refers to that each of the extending direction of an image-capturing end of the second DOF camera 22 and an extending direction of an emitting end of the second collimated light source 23 has a second inclination angle of 15-75 degrees from the upper surface 10 and lower surface 11 of the glass substrate 1, and preferably the second inclination angle of 30-45 degrees. Further in FIG. 4, the first collimated light source 24 and first depth of field camera 21 are diagonally arranged, and the second collimated light source 23 and second DOF camera 22 are diagonally arranged. Further, the first inclination angle can be identical to or different from the second inclination angle, and the present disclosure is not limited thereto.

The microcontroller 25 is further electrically connected with second depth of field camera 22 and second collimated light source 23, and is configured to control the second depth of field camera 22 and second collimated light source 23. The second collimated light source 23 is configured to emit the second collimated beam L2 that obliquely irradiates the glass substrate 1. The color (or optical band) of the first collimated beam L1 is different from the color (or optical band) of the second collimated beam L2. The second depth of field camera 22 is configured to obtain the second image, and the microcontroller 25 is configured to obtain at least one detection result of at least one glass substrate via 12 according to first image and the second image. Each of the color of the first collimated beam L1 and the color of the second collimated beam L2 can be selected from red, green and blue, and the color of the first collimated beam L1 is different from the color of the second collimated beam L2, but the present disclosure is not limited thereto. In addition, the collimation level of the second collimated beam L2 and the maximum determination depth of the second depth of field camera 22 relates to the via depth of the glass substrate via 12, i.e., the thickness T of the glass substrate 1.

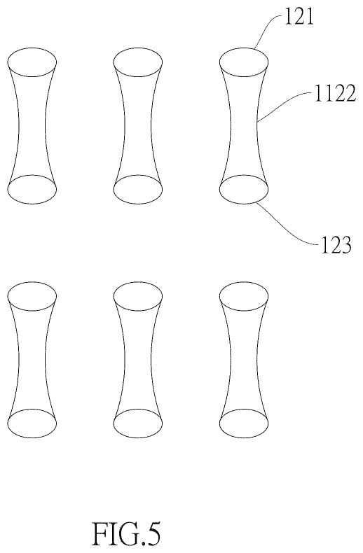

Please refer to FIG. 5. FIG. 5 a schematic diagram illustrating a first image and/or a second image. according to an embodiment of the present disclosure. In an embodiment where only the first depth of field camera 21 and the first collimated light source 24 are adopted without adopting the second depth of field camera 22 and second collimated light source 23, the first image reveals the upper opening 121, the lower opening 123 and the via 122 of the at least one glass substrate via 12 of the glass substrate 1, and further reveals a part of glass substrate 1 near the upper opening 121, the lower opening 123 and the via 122. The upper opening 121, the lower opening 123 and the via 122 in the first image form a dog-bone shape unit. The color of the dog-bone shape unit is the color of the first collimated beam L1, and the color of an area outside the dog-bone shape unit is different from the color of the first collimated beam L1. For example, the color of the area outside the dog-bone shape unit may be darker than the color of the first collimated beam L1.

In an embodiment that the first depth of field camera 21, the first collimated light source 24, the second DOF camera 22 and the second collimated light source 23 are adopted, the first image reveals the upper opening 121, the lower opening 123 and the via 122 of the at least one glass substrate via 12 of the glass substrate 1, and further reveals the part of glass substrate 1 near the upper opening 121, the lower opening 123 and the via 122. The upper opening 121, the lower opening 123 and the via 122 in the first image form the dog-bone shape unit. The color of the dog-bone shape unit is the color of the first collimated beam L1, and the color of an area outside the dog-bone shape unit is a mixed color of the color of the first collimated beam L1 and the color of the second collimated beam L2.

The second image reveals the upper opening 121, the lower opening 123, the via 122 of at least one glass substrate via 12 of the glass substrate 1, and further reveals the part of the glass substrate 1 near the upper opening 121, the lower opening 123 and the via 122. The upper opening 121, the lower opening 123 and the via 122 in the second image form a dog-bone shape unit, and the color of the dog-bone shape unit is the color of the second collimated beam L2, and the color of an area outside the dog-bone shape unit is a mixed color of the color of the first collimated beam L1 and the color of the second collimated beam L2.

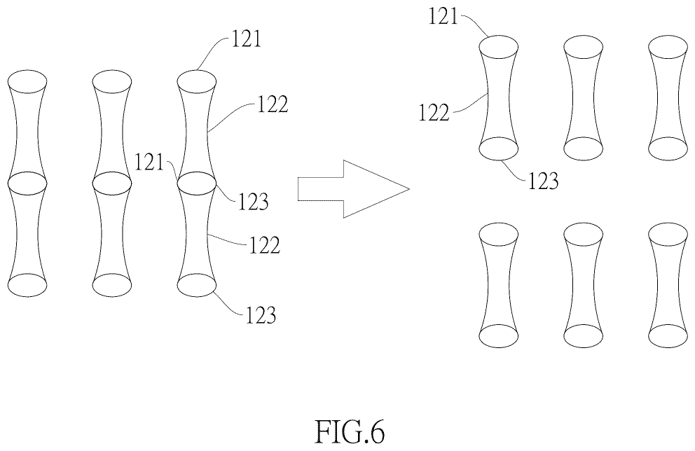

Next, please refer to FIG. 6. FIG. 6 a schematic diagram illustrating a first image and/or a second image according to another embodiment of the present disclosure. Since the present disclosure obtains the waist depth D of the glass substrate via 12 by means of obliquely irradiating and obliquely capturing, under some circumstances, two adjacent dog-bone shape unit in the same image may overlap with each other. As shown in the left side of FIG. 6, the lower opening 123 of one dog-bone shape unit overlaps with the upper opening 121 of another dog-bone shape unit.

To facilitate users to check the first image and/or the second image, the microcontroller 25 may further be configured to process two overlapped dog-bone shape units in the first image so as to separate these two overlapped dog-bone shape units in the first image from each other, and process two overlapped dog-bone shape units in the second image so as to separate these two overlapped dog-bone shape units in the second image from each other, as shown in the right side of FIG. 6. Further, in the situation where the first collimated light source 24 and second collimated light source 23 are adopted, the microcontroller 25 may identify two dog-bone shape units of different colors. After the microcontroller 25 distinguishes two dog-bone shape units of different colors, an algorithm can be used to separate the two overlapped dog-bone shape units in the first image, and two overlapped dog-bone shape units in the second image may be also processed.

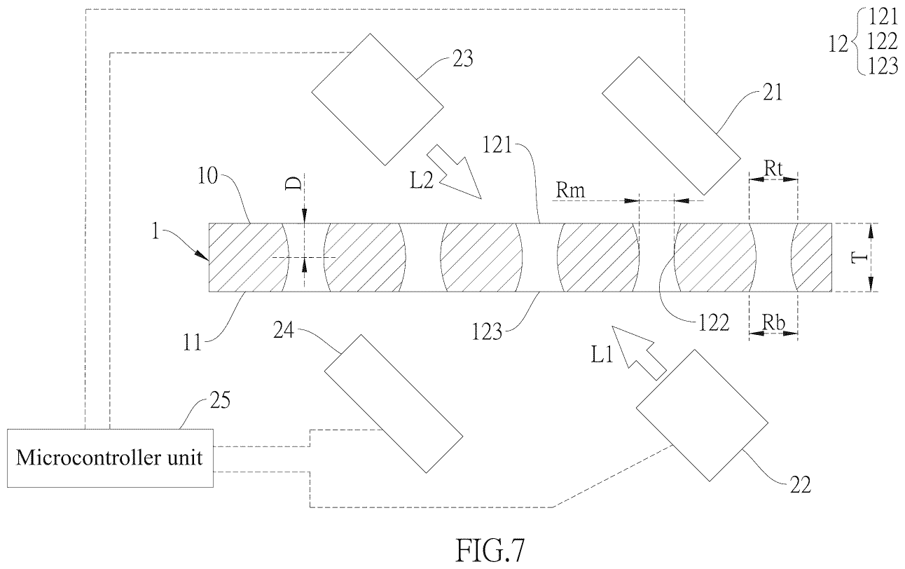

Further referring to FIG. 7, FIG. 7 is a schematic side view cross section diagram showing that a glass substrate is detected by a via waist depth detection device for the through glass via substrate according to another embodiment of the present disclosure. Compared with the embodiment of FIG. 4, the positions of the first collimated light source 24 and second depth of field camera 22 are exchanged in the embodiment of FIG. 7. In FIG. 7, the first collimated light source 24 and second collimated light source 23 are diagonally arranged, and the first DOF camera 21 and second DOF camera 22 are diagonally arranged. The first depth of field camera 21 and second collimated light source 23 are arranged above the glass substrate 1, and the second depth of field camera 22 and first collimated light source 24 are arranged below the glass substrate 1. However, the present disclosure neither limits the first collimated light source 24 and the first depth of field camera 21 to be arranged diagonally, nor the second collimated light source 23 and the second depth of field camera 22 to be arranged diagonally.

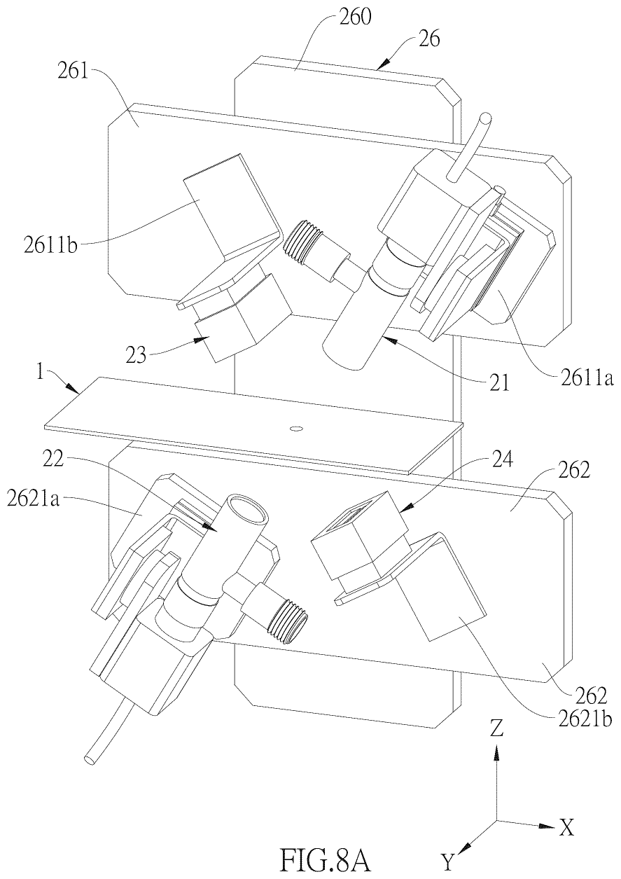

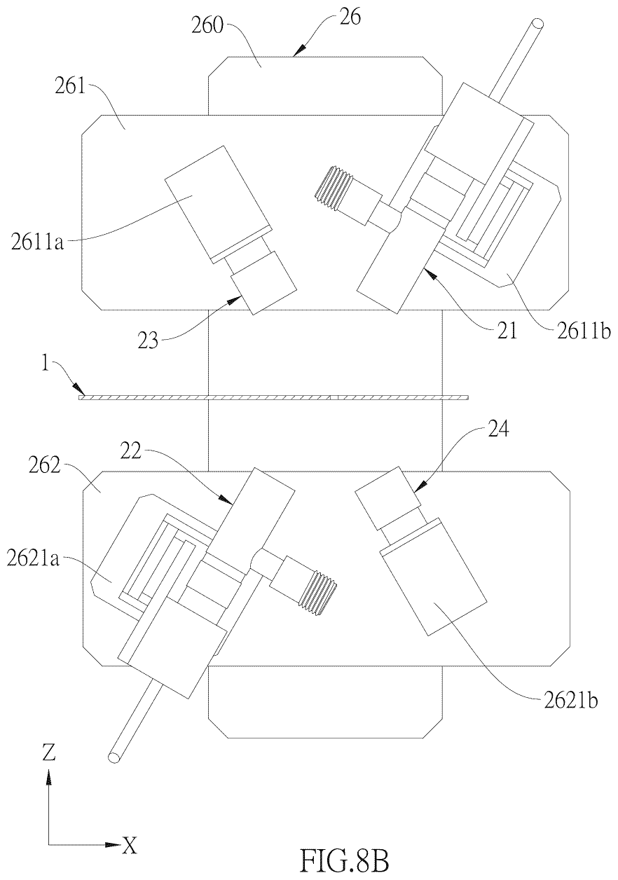

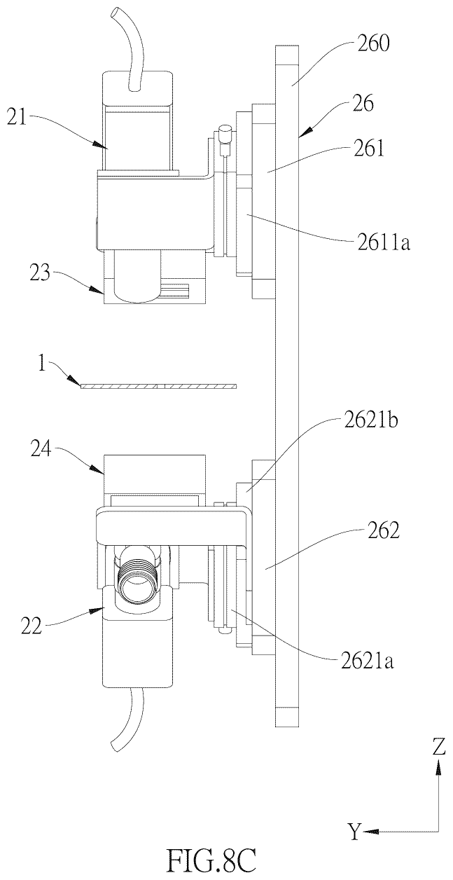

Moreover, the via waist depth detection device of the through glass via substrate further comprises a main frame body (not shown) and a glass substrate supporting structure (not shown). The glass substrate supporting structure is arranged in the main frame body, and is configured to touch at least one part of the glass substrate 1 (e.g., the four corners thereof, but the present disclosure is not limited thereto), so as to support the glass substrate 1. In addition, please refer to FIG. 8A to FIG. 8C. FIG. 8A is a schematic perspective view diagram illustrating a part of the structure of the via waist depth detection device for the through glass via substrate according to another embodiment of the present disclosure, FIG. 8B is a schematic front view diagram illustrating a part of the structure of the via waist depth detection device for the through glass via substrate according to another embodiment of the present disclosure, and FIG. 8C is a schematic side view diagram illustrating a part of the structure of the via waist depth detection device for the through glass via substrate according to another embodiment of the present disclosure. In addition to the main frame body (not shown) and the glass substrate supporting structure (not shown), the via waist depth detection device of the TGV glass substrate further comprises a base structure 26 for supporting and fixing the first depth of field camera 21, the second depth of field camera 22, the second collimated light source 23 and the first collimated light source 24, wherein the base structure 26 comprises a common base 260, an upper base 261, a lower base 262, a first base 2611a, a second base 2611b, a third base 2621a and a fourth base 2621b. The upper base 261, the lower base 262 are arranged on an upper half and a lower half of the common base 260 respectively, the first base 2611a and the second base 2611b are arranged on a left half and a right half of the upper base 261 respectively, the third base 2621a and the fourth base 2621b are arranged on a left half and a right half of the lower base 262 respectively, the first base 2611a and the second base 2611b are configured to support and fix the first depth of field camera 21 and the second collimated light source 23 respectively, and the third base 2621a and the fourth base 2621b are configured to support and fix the second depth of field camera 22 and the first collimated light source 24 respectively.

In an embodiment, if the size of the glass substrate 1 is not too large, the first image and the second image of the complete glass substrate 1 can be obtained without the need for moving the first DOF camera 21, the second DOF camera 22, the second collimated light source 23 and the first collimated light source 24. In this way, the common base 260 may be designed to be fixed to the main frame body, and the glass substrate supporting structure may be designed to be fixed to the main frame body, so that the glass substrate 1 does not move relative to the first depth of field camera 21, the second depth of field camera 22, the second collimated light source 23 and the first collimated light source 24. In an embodiment, if the size of the glass substrate 1 is relatively large, and the first depth of field camera 21, the second depth of field camera 22, the second collimated light source 23 and the first collimated light source 24 have to move so as to obtain the first image and second image of the complete glass substrate 1. In this way, there is a need for a design that the glass substrate 1 is able to move relative to the first depth of field camera 21, the second depth of field camera 22, the second collimated light source 23 and the first collimated light source 24. In this way, it can be designed that the common base 260 is fixed to the main frame body while the glass substrate supporting structure is removably arranged in the main frame body, or the common base 260 is removably arranged in the main frame body while the glass substrate supporting structure is fixed to in the main frame body. Further, the via waist depth detection device of the through glass via substrate may further comprises a driving mechanism, which is configured to connect with and move one of the common base 260 and the glass substrate supporting structure, so that the glass substrate 1 can move relative to the first depth of field camera 21, the second depth of field camera 22, the second collimated light source 23 and the first collimated light source 24.

In addition, each of the first base 2611a, the second base 2611b, the third base 2621a and the fourth base 2621b comprises an adjusting structure. The adjusting structure may be, but not limited to, an adjusting washer, an adjustment screw, an adjusting bearing or one other adjusting part. The adjusting structures of the first base 2611a and the second base 2611b can be used to adjust the offsets of the first depth of field camera 21 and the second collimated light source 23, respectively. The aforementioned offset may be the offset in both X and Y axes, or in X, Y and Z axes. The adjusting structures of the third base 2621a and fourth base 2621b can be used to adjust the offsets of the second depth of field camera 22 and the first collimated light source 24, respectively. The aforementioned offset may be the offset in both X and Y axes, or in X, Y and Z axes. However, the present disclosure does not limit the way of carrying out the adjusting structure. In addition, as can be seen from the above in the present disclosure, when the first depth of field camera 21, the second depth of field camera 22, the second collimated light source 23 and the first collimated light source 24 need to move relative to the glass substrate 1, the first depth of field camera 21, the second depth of field camera 22, the second collimated light source 23 and the first collimated light source 24 are designed to move relative to the glass substrate 1 in a linked manner. This provides the advantage that once the adjustment of the offset is done, it can be avoided the offset (which requires readjustment) caused by that any of the first depth of field camera 21, the second depth of field camera 22, the second collimated light source 23 and the first collimated light source 24 move alone. Hence, the above linked manner design can improve the measurement accuracy, or reduce the time and labor cost on adjusting the offset.

Furthermore, based on the above contents, the present disclosure further provides a via waist depth detection method for a through glass via substrate. The via waist depth detection method is executed by a via waist depth detection device for the through glass via substrate. The via waist depth detection device comprises a first depth of field camera and a first collimated light source, the first depth of field camera and the first collimated light source are arranged above and below a glass substrate with at least one glass substrate via respectively, and obliquely face an upper surface and a lower surface of the glass substrate respectively, or alternatively the first depth of field camera and the first collimated light source are arranged below and above the glass substrate respectively, and obliquely face the lower surface and the upper surface of the glass substrate respectively. The via waist depth detection method comprises: controlling, by a microcontroller of the via waist depth detection device of the through glass via substrate, the first depth of field camera and the first collimated light source to make the first collimated light source emit a first collimated beam that obliquely irradiates the glass substrate, and to make the first depth of field camera obtain a first image; and obtaining, by the microcontroller of the via waist depth detection device of the through glass via substrate, at least one detection result of the at least one glass substrate via according to the first image. In addition, when the size of glass substrate is relatively large, the first depth of field camera and the first collimated light source must move so as to obtain the first image of the complete glass substrate, the above via waist depth detection method further comprises: configuring the first depth of field camera and the first collimated light source of the via waist depth detection device for the through glass via substrate to move relative to the glass substrate (i.e., the first depth of field camera and the first collimated light source move altogether while the glass substrate remains still, or the first depth of field camera and first collimated light source remains still while the glass substrate moves).

To summarize, the via waist depth detection device and method for the through glass via substrate provided by the present disclosure adopt an optical detection manner to detect a waist depth of the via of the through glass via substrate without filling lossless molding materials, therefore not only reducing the detection time and cost, but also avoiding the damage of the glass substrate.

The above-mentioned embodiments are only for explaining the technical concepts and characteristics of the present disclosure, and the objective thereof is to make one skilled in the art understand the content of the present disclosure and implement it accordingly, rather than limiting the claimed scope of the present disclosure. That is, all equivalent changes or modifications made in accordance with the spirit of the present disclosure shall fall within the scope of the present disclosure.

1. A via waist depth detection device for a through glass via (TGV) substrate, comprising:
a first depth of field (DOF) camera and a first collimated light source, respectively arranged above and below a glass substrate with at least one glass substrate via, and obliquely facing an upper surface and a lower surface of the glass substrate respectively, or alternatively, respectively arranged below and above the glass substrate, and obliquely facing the lower upper surface and the upper lower surface of the glass substrate respectively; and
a microcontroller, electrically connected with the first depth of field camera and the first collimated light source;
wherein the first collimated light source is configured to emit a first collimated beam which obliquely irradiates the glass substrate, the first depth of field camera is configured to obtain a first image, and the microcontroller is configured to obtain the at least one glass substrate via according to the first image.

2. The via waist depth detection device for the through glass via substrate according to claim 1, wherein the detection result comprises a waist depth of the glass substrate via.

3. The via waist depth detection device for the through glass via substrate according to claim 1, further comprising:
a second depth of field camera and a second collimated light source, wherein when the first depth of field camera and the first collimated light source are respectively arranged above and below the glass substrate, the second depth of field camera and the second collimated light source are respectively arranged below and above the glass substrate, and obliquely face the lower surface and the upper surface of the glass substrate respectively, and when the first depth of field camera and the first collimated light source are respectively arranged below and above the glass substrate and, the second depth of field camera and the second collimated light source are respectively arranged above and below the glass substrate, and obliquely face the upper surface and the lower surface of the glass substrate respectively;
wherein the microcontroller is electrically connected with the second depth of field camera and the second collimated light source, the second collimated light source is configured to emit a second collimated beam which obliquely irradiates the glass substrate; an optical band of the first collimated beam is different from an optical band of the second collimated beam, the second depth of field camera is configured to obtain a second image, and the microcontroller is configured to obtain the at least one detection result of the at least one glass substrate via according to the first image and the second image.

4. The via waist depth detection device for the through glass via substrate according to claim 3, wherein each of a color of the first collimated beam and a color of the second collimated beam are selected from red, green and blue, and the color of the first collimated beam is different from the color of the second collimated beam.

5. The via waist depth detection device for the through glass via substrate according to claim 3, wherein each of an extending direction of an image-capturing end of the first depth of field camera and an extending direction of an emitting end of the first collimated light source has a first inclination angle of 30-45 degrees from the upper surface and the lower surface of the glass substrate, each of an extending direction of an image-capturing end of the second depth of field camera and an extending direction of an emitting end of the second collimated light source has a second inclination angle of 30-45 degrees from the upper surface and the lower surface of the glass substrate, and the first inclination angle is identical to or different from the second inclination angle.

6. The via waist depth detection device for the through glass via substrate according to claim 5, further comprising:
a base structure comprising a common base, an upper base, a lower base, a first base, a second base, a third base and a fourth base, wherein the upper base, the lower base are arranged on an upper half and a lower half of the common base respectively, the first base and the second base are arranged on a left half and a right half of the upper base respectively, the third base and the fourth base are arranged on a left half and a right half of the lower base respectively, the first base and the second base are configured to support and fix the first depth of field camera and the second collimated light source respectively, and the third base and the fourth base are configured to support and fix the second depth of field camera and the first collimated light source respectively.

7. The via waist depth detection device for the through glass via substrate according to claim 6, wherein the common base is fixed in a main frame body, and a glass substrate supporting structure is movably arranged in the main frame body, so that the glass substrate moves relative to the first depth of field camera, the second depth of field camera, the second collimated light source and the first collimated light source in response to movement of the glass substrate supporting structure; or alternatively, the common base is moveably arranged in the main frame body, and the glass substrate supporting structure is fixed in the main frame body, so that the glass substrate moves relative to the first depth of field camera, the second depth of field camera, the second collimated light source and the first collimated light source in response to movement of the common base.

8. The via waist depth detection device for the through glass via substrate according to claim 3, wherein the first image reveals an upper opening, a lower opening and a via of the at least one glass substrate via of the glass substrate, and reveals a part of the glass substrate near the upper opening, the lower opening and the via, wherein the upper opening, the lower opening and the via in the first image form a dog-bone shape unit, a color of the dog-bone shape unit is a color of the first collimated beam, and a color of an area outside the dog-bone shape unit is a mixed color of the color of the first collimated beam and a color of the second collimated beam.

9. The via waist depth detection device for the through glass via substrate according to claim 8, wherein the second image reveals an upper opening, a lower opening and a via of the at least one glass substrate via of the glass substrate, and reveals a part of the glass substrate near the upper opening, the lower opening and the via, wherein the upper opening, the lower opening and the via in the second in image form another dog-bone shape unit, a color of the other dog-bone shape unit is a color of the second collimated beam, and a color outside the other dog-bone shape unit is a mixed color of the color of a first collimated beam and the color of the second collimated beam.

10. The via waist depth detection device for the through glass via substrate according to claim 9, wherein the microcontroller is further configured to process two overlapped dog-bone shape units in the first image so as to separate the two overlapped dog-bone shape units in the first image from each other, and process two overlapped dog-bone shape units in the second image so as to separate the two overlapped dog-bone shape units in the second image from each other.

11. A via waist depth detection method for a through glass via (TGV) substrate, executed by a via waist depth detection device for the through glass via substrate, the via waist depth detection device comprises a first depth of field (DOF) camera and a first collimated light source, the first depth of field camera and the first collimated light source are arranged above and below a glass substrate with at least one glass substrate via respectively, and obliquely face an upper surface and a lower surface of the glass substrate respectively, or alternatively, the first depth of field camera and the first collimated light source are respectively arranged below and above the glass substrate, and obliquely face the lower surface and the upper surface of the glass substrate respectively; and the via waist depth detection method comprises:
controlling, by a microcontroller of the via waist depth detection device for the through glass via substrate, the first depth of field camera and the first collimated light source to make the first collimated light source emit a first collimated beam that obliquely irradiates the glass substrate and to make the first DOF camera obtain a first image; and
obtaining, by the microcontroller of the via waist depth detection device for the through glass via substrate, at least one detection result of the at least one glass substrate via according to the first image.

12. The via waist depth detection method for the through glass via substrate according to claim 11, wherein the detection result comprises a waist depth of the glass substrate via.

13. The via waist depth detection method for the through glass via substrate according to claim 11, wherein each of an extending direction of an image-capturing end of the first DOF camera and an extending direction of an emitting end of the first collimated light source has a first inclination angle of 30-45 degrees from the upper surface and the lower surface of the glass substrate.

14. The via waist depth detection method for the through glass via substrate according to claim 11, wherein the first image reveals an upper opening, a lower opening and a via of the at least one glass substrate via of the glass substrate, and reveals a part of the glass substrate near the upper opening, the lower opening and the via; the upper opening, the lower opening and the via in the first image form a dog-bone shape unit, a color of the dog-bone shape unit is a color of the first collimated beam, and a color of an area outside the dog-bone shape unit is different from the color of the first collimated beam.
